(19) United States
(12) Patent Application Publication
(10) Pub. No.: US 2006/0195737 A1
(43) Pub. Date: Aug. 31, 2006

(54) System and method for characterization of certain operating characteristics of devices

(75) Inventor: Norman Karl James, Liberty Hill, TX (US)

Correspondence Address: IBM CORP (YA);C/O YEE & ASSOCIATES PC, P.O. BOX 802333, DALLAS, TX, 75380, US

(73) Assignee: International Business Machines Corporation, Armonk, NY (US)

(21) Appl. No.: 11/055,856

(22) Filed: Feb. 11, 2005

(51) Int. Cl. G01R 31/28

(52) U.S. Cl. 714/726

(57) ABSTRACT

A system and method is provided for improving integrated circuit device characterization without requiring external tester hardware. On-chip circuitry is provided to measure the delay of a signal through a given scan chain when the scan chain latches have been placed in flush mode. A control signal generated by the on-chip circuitry simultaneously generates a timing measurement signal as well as initiates a counter/timer to count/time the amount of time it takes for the timing measurement signal to pass through certain operational circuitry of the integrated circuit device. The resolution of the measurement is the resolution of the integrated circuit device's global clock.

### BACKGROUND OF THE INVENTION

1. Technical Field

The present invention is directed to device characterization techniques, and in particular is related to techniques used to characterize the operating speed of a device such as an electrical, electronic or optical integrated circuit device, or combination thereof.

2. Description of Related Art

Integrated circuit devices continue to shrink in size as technological and manufacturing improvements are made. As the size of integrated circuit devices decreases, the operating speed of such devices increases as delays such as signal propagation delays between individual components (such as transistors, capacitors, etc) decreases due to shorter electron travel distances resulting from such size decrease.

Measuring the process speed of an integrated circuit device can help qualify and quantify new integrated circuit designs. For example, during the design phase of an integrated circuit device, certain value distributions are assumed for process parameters, chip temperature, and circuit voltage. In addition, the tools that are used for performance prediction have accuracy limitations, with associated guard bands. On the basis of these assumptions and calculations, a cycle time is chosen as a design point. This is the fundamental clock period for the device being developed and, generally speaking, represents the time limit for data to propagate from one state latch to another state latch. FIG. 1 shows at 100 a typical latch-to-latch path and cycle-time definition. Boundary or scan cell 102 has L1 and L2 latches clocked by clock signals C1CLK and C2CLK, the output of which feeds into combinational logic 104. The output of combinational logic 104 feeds into boundary or scan cell 106 which also has L1 and L2 latches clocked by C1CLK and C2CLK. The C2CLK clock period is shown to be a typical cycle time for the device. The time period from the rising edge of the C2CLK launch clock to the falling edge of the C1CLK capture clock is shown to be a typical latch-to-latch path limit.

Extensive test characterization and diagnostic work has shown that actual physical chips can have speeds significantly different from predictions, and what limits the cycle time is often different from what was expected. This is due both to timing tool inaccuracy and to the process spread around the timing tool design point. Timing simulation is generally accurate to within 5%. A 5% cycle-time improvement, however, is significant, and once chips arrive there is an intense effort not only to verify functionality but to maximize performance by adjusting voltage, temperature, process-in fact, or whatever variable can be adjusted in the short, several-month functional evaluation period before committing the design to mass-scale production. The extent to which these variables are adjusted depends on existing design margins, how quickly changes can be made, and the ability to change each parameter. It is fundamentally an empirical, iterative process because of the limitations of simulation and modeling. A major part of performance optimization plans for these iterations.

Boundary scan is a methodology allowing complete controllability and observability of the boundary pins of a JTAG compatible device via software control. This capability enables in-circuit testing of devices without the need of bed-of-nail in-circuit test equipment. Scan chains are used as a part of the design of an integrated circuit device to provide such boundary scan capabilities.

Chips are sorted for performance on the basis of a “flush” delay measurement through a series of latches in the scan chain of each chip. Scan clocks are held in their active state, and a data transition on the chip scan-in port “flushes” through the chain to the scan-out port. Thus, a flush delay measurement through a scan chain can indicate the process speed of an integrated circuit or chip. Typically, a tester device is connected to the silicon and used to put the latches in flush mode and time the delay measurement through the chain. This type of testing is limited, however, since it cannot be performed after a chip has been installed in a system. In addition, the tester must use its own clock to mark the beginning and end of the flush delay measurement, thus limiting the resolution of the measurement to the granularity of the clock available to the tester's software. Since it is often times necessary to determine the process speed of a chip in a system, a new method is needed to measure flush delay. In addition, since new devices may be designed using a manufacturing process that yields substantially faster operating characteristics from that used for the tester itself, there is a need to match performance characteristics of the device itself as a part of characterizing the device.

### SUMMARY OF THE INVENTION

A system and method is provided for improving integrated circuit device characterization without requiring external tester hardware. On-chip circuitry is provided to measure the delay of a signal through a given scan chain when the scan chain latches have been placed in flush mode. A control signal generated by the on-chip circuitry simultaneously generates a timing measurement signal as well as initiates a counter/timer to count/time the amount of time it takes for the timing measurement signal to pass through certain operational circuitry of the integrated circuit device. The resolution of the measurement is the resolution of the integrated circuit device's global clock.

### BRIEF DESCRIPTION OF THE DRAWINGS

The novel features believed characteristic of the invention are set forth in the appended claims. The invention itself, however, as well as a preferred mode of use, further objectives and advantages thereof, will best be understood by reference to the following detailed description of an illustrative embodiment when read in conjunction with the accompanying drawings, wherein:

FIG. 1 describes various timing parameters associated with a device having scan logic such as boundary scan logic.

FIG. 2 depicts a traditional L1/L2 latch used as a scan latch in a boundary scan design.

FIG. 3 depicts a device having boundary scan capabilities.

FIG. 4 depicts on-chip control for self-determination of the process speed of a device such as an integrated circuit device.

FIG. 5 depicts a flow diagram for control logic used to determine an amount of time for signal propagation through a scan chain.

### DETAILED DESCRIPTION OF THE PREFERRED EMBODIMENT

The present invention is based upon an integrated circuit design having full-scan capabilities in which every latch is controllable and observable through scan ports on the chip. Latches are connected serially by a scan path and are clocked serially by scan clocks. Referring now to FIG. 2, there is shown a basic L1/L2 latch at 200. Inputs to latch 202 are shown as SCAN, ACLK, DATA, C1CLK and C2CLK. ACLK latches the value on the SCAN input port into the latch 202. C1CLK latches the value on the DATA input port into latch 202. C2CLK latches data from the L1 master latch 204 into the L2 slave latch 206 of latch 202. When ACLK and C2CLK are both active, the value on the SCAN input port is flushed to the OUT output port of latch 202.

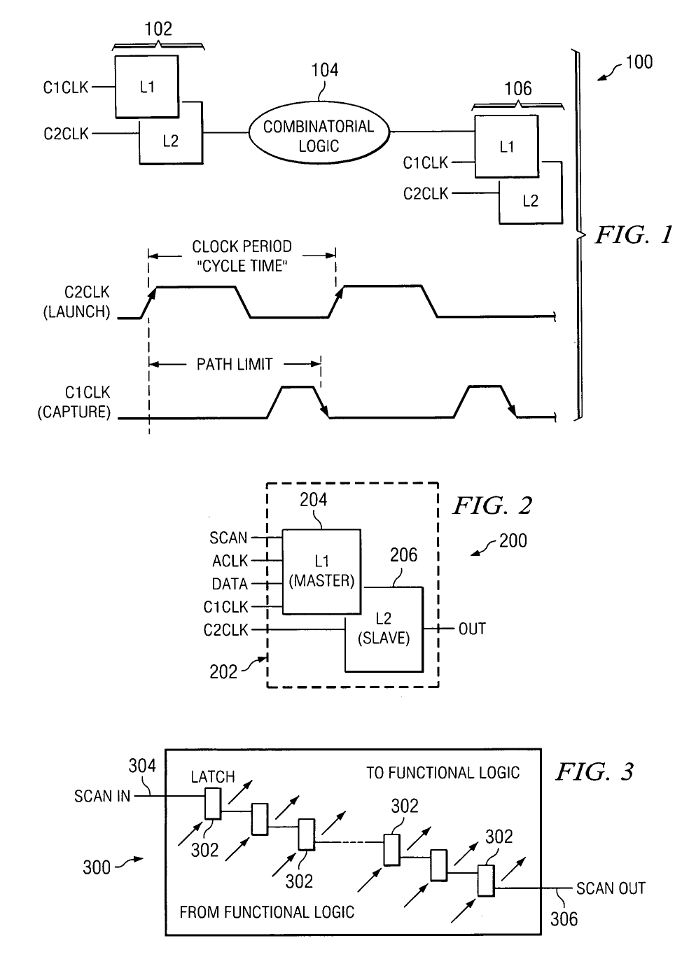

FIG. 3 shows a traditional scan path at 300. A plurality of L1/L2 latches 302, a representative one such L1/L2 latch being shown at 202 in FIG. 1, are serially-coupled together. The first latch 302 in the chain has its SCAN input port coupled to an external SCAN IN port 304, and the last latch 302 in the chain has its OUT output port coupled to an external SCAN OUT port 306, thus providing a scan path from SCAN IN 304, through each intervening latch 302, and then ending at SCAN OUT 306. Also shown by the arrows are the interconnections to other functional logic within the integrated circuit device which are operational when the device is functioning in its normal (i.e. non-test) operating environment, with logic or net signals from the other functional logic shown to the left of the latches 302, and the outputs of the latches 302 feeding other functional logic as indicated by the arrows to the right of the latches 302.

The present invention adds support circuitry to an integrated circuit device to enable the device itself to perform or measure process speed of its own circuitry, thereby eliminating a need for an external tester to perform such process speed determination.

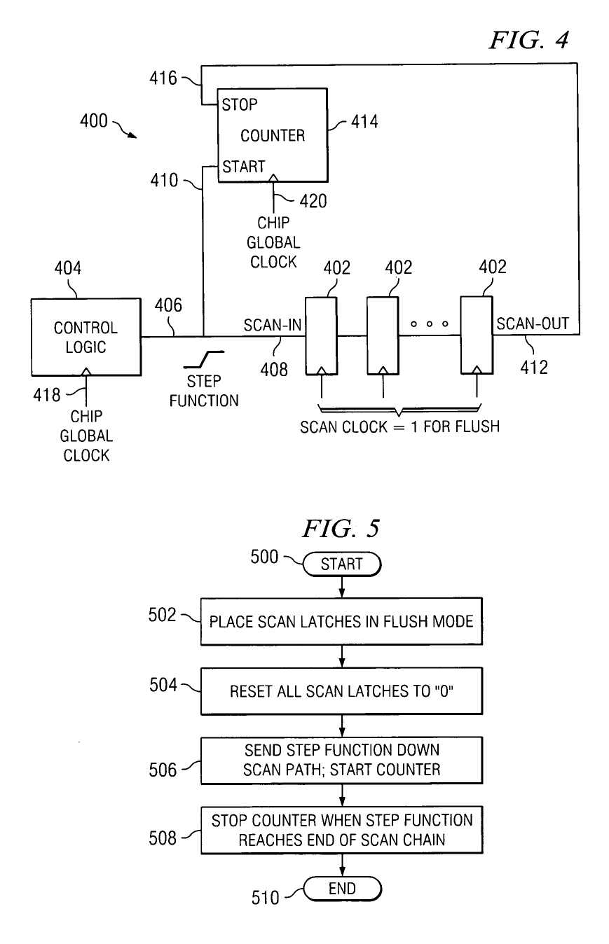

Turning now to FIG. 4, there is shown at 400 a technique for flush delay measurement that can be used to measure the flush delay of a device and therefore measure the characteristic operating speed of the device. A scan chain comprising a plurality of scan latches 402 are serially coupled together, as was previously shown in FIG. 3, to provide boundary scan functionality. The normal functional logic provided by the integrated circuit device is not shown for ease of clarity in focusing on the particular aspects of the present flush delay measurement technique. The flush measurement technique is controlled by control logic 404, as will be further described in detail below. The control logic 404 provides a signal 406 to the SCAN-IN input 408 of the first latch 402 and to the START input 410 of the counter or timer 406. The SCAN-OUT output port 412 of the last latch 402 of the scan chain is coupled to the STOP input control port of counter 414 at 416. A CHIP GLOBAL CLOCK signal is provided to both a clock input of the control logic at 418 and a clock input of the counter/timer at 420.

The operation of the flush delay measurement technique will now be described with reference to the flow diagram depicted in FIG. 5. Processing begins at 500 and proceeds to 502 where control logic 404 (as shown in FIG. 4) places the scan latches of the scan chain (such as is shown by elements 402 in FIG. 4) in flush mode by holding the scan clocks at a logic ‘1’ (of course, an alternate embodiment could reverse all logic control signals and use a logic ‘0’ as the active logic control state). These scan clocks are shown in FIG. 2 as the C1CLK and the C2CLK scan clocks. Then, at step/state 504, control logic 404 places a logic ‘0’ on the scan path (i.e. at its output 406) sufficiently long enough for all the scan latches to reset to a ‘0’ while in the flush mode. Then, at step/state 506, control logic 404 sends a step function (a ‘0’ to ‘1’ transition) from its output 406 down the scan path. This step function, where the signal transitions from a logic ‘0’ to a logic ‘1’, also initiates counting/timing of the counter/timer as the output of the control logic is also coupled to the START input 410 of counter/timer 414. When the step function has progressed or flushed through all the serially-coupled scan latches 402, the SCAN-OUT output 412 transitions from ‘0’ to ‘1’ and since this output is coupled to the STOP input 416 of counter/timer 414, this flushed step function signal signals to the counter/timer to stop counting/timing at the time at which step function has transitioned through all the latches 402 in the scan chain (step 508). Thus, the counter/timer is able to determine the time it takes for the step function to travel through the flushed scan path. Since the counter/timer is clocked via a high-speed CHIP GLOBAL CLOCK which runs at a known frequency, it is possible to precisely determine the amount of time it took for the step function to transition through all latches of the scan path, thereby providing an extremely accurate measurement of the process speed of the integrated circuit device using self-measurement techniques. Processing then ends at 510.

The counter/timer can now be read by any of a number of different techniques, depending upon the particular device implementation. For example, many designs have some type of embedded controller or processor that can be used to access the counter/timer to read the stored counter/timer value. The embedded controller or processor may be either a standard macro that is embedded in the device, or a custom controller such as a programmable logic device state machine controller that can be used to access the counter. Alternatively, the control logic 404 can read the counter/timer using standard counter/timer access techniques.

Thus, there is provided an improved flush delay measurement technique which utilizes an integrated circuit device's scan chain in conjunction with on-chip control logic and a high performance counter/timer to provide an on-chip self-determination of the process speed that the integrated circuit device operates at.

The description of the present invention has been presented for purposes of illustration and description, and is not intended to be exhaustive or limited to the invention in the form disclosed. Many modifications and variations will be apparent to those of ordinary skill in the art. For example, while the present invention is primarily described herein using descriptions of electronic integrated circuits devices, the presently described techniques are equally applicable to other types of devices, such as optical devices and electro-optical devices. The embodiment was chosen and described in order to best explain the principles of the invention, the practical application, and to enable others of ordinary skill in the art to understand the invention for various embodiments with various modifications as are suited to the particular use contemplated.

What is claimed is:

1. A method for determining operating characteristics of a device, comprising steps of:
simultaneously providing a input signal transition to an input of a scan chain and an input of a counter; and
providing an output signal transition from an output of the scan chain to another input of the counter, wherein the input signal transition starts the counter and the output signal transition stops the counter.

2. The method of claim 1, wherein the output signal transition corresponds to the input signal transition but delayed in time according to a delay of the scan chain.

3. The method of claim 1 wherein the scan chain is comprised of a plurality of scan latches serially coupled together.

4. A method for determining operating characteristics of a device having a plurality of scan latches serially coupled together, comprising steps of:
placing each of the scan latches in a flush mode;
sending a step function to an input of a first scan latch and concurrently starting a counter; and
stopping the counter when the step function reaches the end of the scan chain.

5. The method of claim 4, wherein each of the scan latches are reset after being place in the flush mode.

6. The method of claim 5, further comprising a step of determining process speed of the device using the counter.

7. An integrated circuit device having circuitry for self-determining process speed of the integrated circuit device.

8. The integrated circuit device of claim 7, wherein the circuitry comprises a control portion that generates a control signal that concurrently initiates (i) a timing transition signal and (ii) counting of a counter.

9. The integrated circuit device of claim 8, wherein the integrated circuit device comprises a scan chain for testing the integrated circuit device, and the timing transition signal passes through the scan chain and then to a control of the counter to halt counting of the counter.

10. The integrated circuit device of claim 7, wherein the integrated circuit device includes timing circuitry for measuring a flush delay of test circuitry within the integrated circuit device.

11. The integrated circuit device of claim 10, wherein the test circuitry comprises a scan chain.

12. The integrated circuit device of claim 11, wherein the scan chain comprises a plurality of scan latches serially coupled together.

13. The integrated circuit device of claim 7, wherein the circuitry comprises:
a scan chain; and
control circuitry that places the scan chain in a flush mode and generates a control signal that (i) propagates through the scan chain and (ii) initiates a counter.

14. The integrated circuit device of claim 13, wherein the scan chain comprises a plurality of latches that are serially coupled together.

15. The integrated circuit device of claim 14, wherein the plurality of latches each has a scan-in input and a scan-out output, and a first latch of the plurality of latches has its scan-in input coupled to the control circuitry and its scan-out output coupled to a second latch's scan-in input, and wherein a last latch of the plurality of latches has its scan-in input coupled to a preceding latch's scan-out output and has its scan-out output coupled to a control input of the counter.
